(19) United States
(12) Patent Application Publication
(10) Pub. No.: US 2025/0044236 A1
(43) Pub. Date: Feb. 6, 2025

(54) INSPECTION APPARATUS, LINEARLY MOVABLE BEAM DISPLACER, AND METHOD

(71) Applicant: ASML Netherlands B.V., Veldhoven (NL)

(72) Inventors: Douglas C. CAPPELLI, Norwalk, CT (US); Ferry ZIJP, Nuenen (NL); Bram Antonius Gerardus LOMANS, Eindhoven (NL); Bastiaan Lambertus Wilhelmus Marinus VAN DE VEN, Rosmalen (NL)

(73) Assignee: ASML Netherlands B.V., Veldhoven (NL)

(21) Appl. No.: 18/843,138

(22) PCT Filed: Feb. 17, 2023
(86) PCT No.: PCT/EP2023/054116

§ 371 Date: Aug. 30, 2024

Related U.S. Application Data
(60) Provisional application No. 63/315,838, filed on Mar. 2, 2022.

(51) Int. Cl. G01N 21/88; G01N 21/95; G01N 21/956; G02B 7/18; G02B 7/182

(52) U.S. Cl. CPC G01N 21/8806; G01N 21/9501; G01N 21/956; G02B 7/1805; G02B 7/1822

(57) ABSTRACT

An inspection apparatus includes a radiation source, an optical system, and a detector. The radiation source is configured to generate a beam of radiation. The optical system is configured to receive and direct the beam along an optical axis and toward a target so as to produce scattered radiation from the target. The optical system includes a beam displacer. The beam displacer includes two or more reflective surfaces. The beam displacer is configured to receive the beam along the optical axis, perform reflections of the beam so as to displace the optical axis of the beam, move linearly in at least a first dimension to shift the displaced optical axis, and preserve an optical property of the beam such that the optical property is invariant to the linear movement. The detector is configured to receive the scattered radiation and to generate a measurement signal based on the scattered radiation.

### CROSS-REFERENCE TO RELATED APPLICATIONS

This application claims priority of U.S. application 63/315,838 which was filed on Mar. 2, 2022 and which is incorporated herein in its entirety by reference.

### FIELD

The present disclosure relates to directing beams of radiation, for example, devices for adjusting a beam's optical axis while maintaining an optical property of the beam for use in conjunction with inspection and lithographic tools.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

### SUMMARY

Accordingly, it is desirable to improve design improved optical system that allow for parallel measurements of multiple inspection targets.

In some embodiments, an inspection apparatus comprises a radiation source, an optical system, and a detector. The radiation source is configured to generate a beam of radiation. The optical system is configured to receive and direct the beam along an optical axis and toward a target so as to produce scattered radiation from the target. The optical system comprises a beam displacer. The beam displacer comprises two or more reflective surfaces. The beam displacer is configured to receive the beam along the optical axis, perform reflections of the beam so as to displace the optical axis of the beam, move linearly in at least a first dimension to shift the displaced optical axis, and preserve an optical property of the beam such that the optical property is invariant to the linear movement. The detector is configured to receive the scattered radiation and to generate a measurement signal based on the scattered radiation.

In some embodiments, an optical element comprises at least two reflective surfaces. The reflective surfaces are configured with respect to each other to receive a beam of radiation along an optical axis. Reflections of the beam are performed so as to displace the optical axis of the beam. The optical element is moved linearly in at least a first dimension to shift the displaced optical axis. An optical property of the beam is preserved such that the optical property is invariant to the linear movement.

In some embodiments, a method is performed comprising one or more of the following operations. Receiving a beam of radiation along an optical axis at a beam displacer. Performing reflections of the beam so as to displace the optical axis of the beam using two or more reflective surfaces of the beam displacer. Moving the beam displacer linearly in at least a dimension to shift the displaced optical axis. Preserving an optical property of the beam such that the optical property of the beam along the deflected optical axis is invariant to the linear movement. Directing the beam along the deflected optical axis toward a target so as to produce scattered radiation from the target.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIGS. 4A and 4B show schematics of inspection apparatuses, according to some embodiments.

FIG. 5 shows a schematic of an optical system, according to some embodiments.

FIG. 6 shows a schematic of a beam displacer, according to some embodiments.

FIG. 7 shows a schematic of an optical system, according to some embodiments.

FIG. 8 shows a schematic of a mounting arrangement for the optical system, according to some embodiments.

FIG. 9 shows a flowchart of a method, according to some embodiments

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

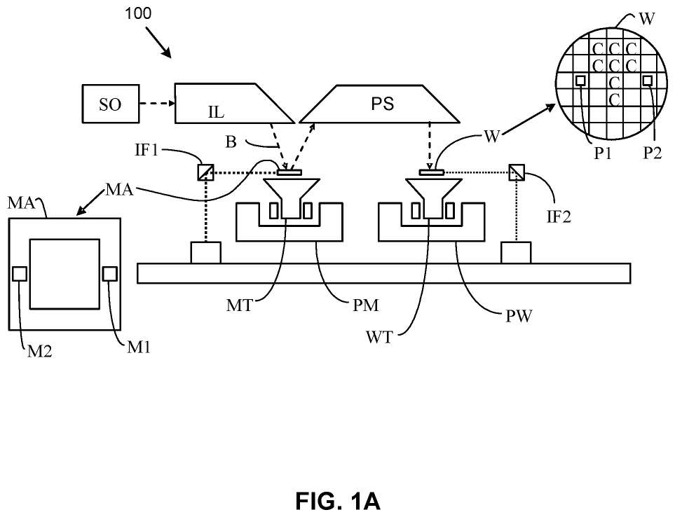

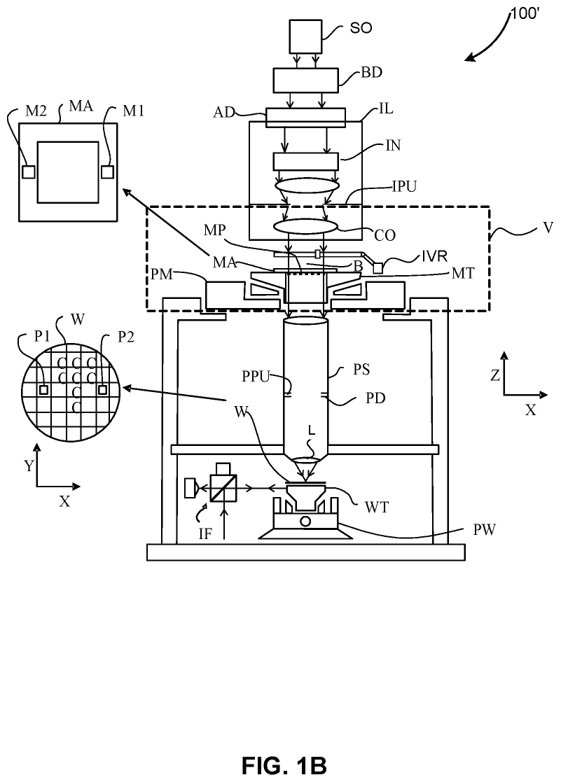

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The terms “inspection apparatus,” “metrology system,” or the like may be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system.

Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “o-outer” and “o-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-) magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

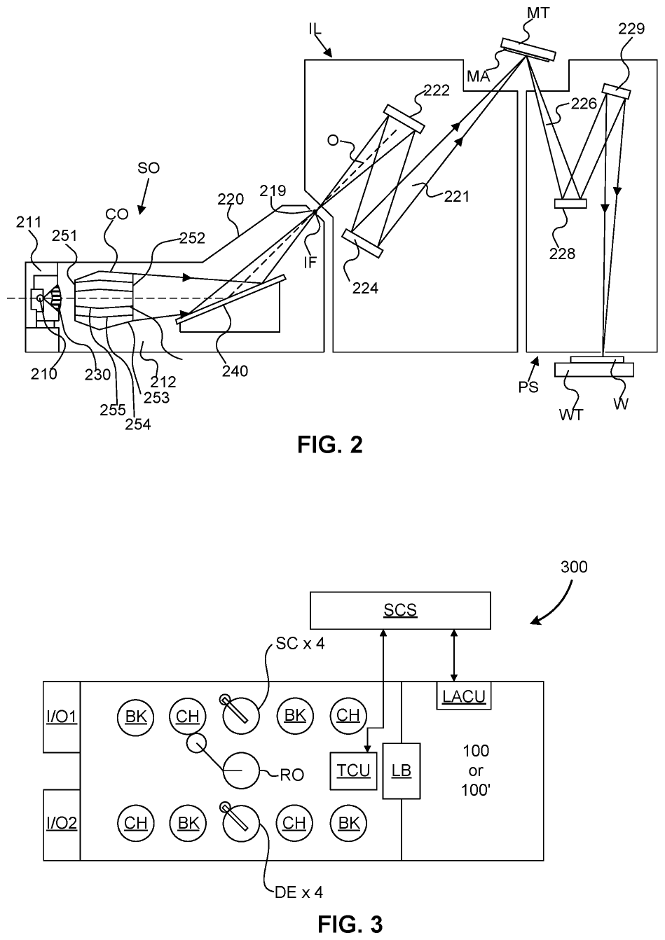

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

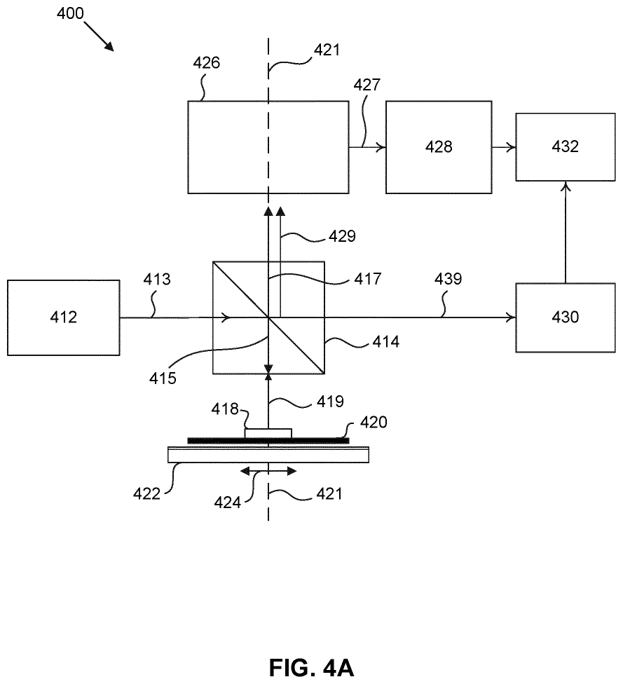

FIG. 3 shows a lithographic cell 300, also sometimes referred to a lithocell or cluster, according to some embodiments. Lithographic apparatus 100 or 100′ may form part of lithographic cell 300. Lithographic cell 300 may also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

### Exemplary Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement may be performed using the techniques described in U.S. Publication No. 2009/195768 A (Bijnen et al.), however. The full contents of both of these disclosures are incorporated herein by reference.

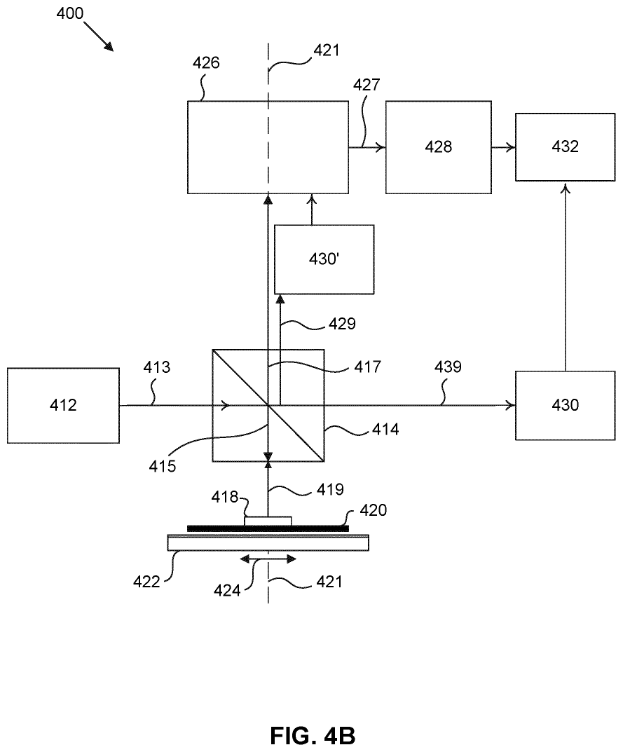

FIG. 4A shows a schematic of a cross-sectional view of an inspection apparatus 400 that may be implemented as a part of lithographic apparatus 100 or 100′, according to some embodiments. In some embodiments, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate may ensure accurate exposure of one or more patterns on the substrate.

In some embodiments, inspection apparatus 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands may be within a spectrum of wavelengths between about 500 nm to about 900 nm. In another example, the one or more passbands may be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values may improve long-term stability and accuracy of alignment systems (e.g., inspection apparatus 400) compared to the current alignment apparatuses.

In some embodiments, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some embodiments, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars may alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, may be input to the reconstruction process, performed by processing unit PU, from knowledge of the printing step and/or other scatterometry processes.

In some embodiments, beam splitter 414 can be further configured to receive diffraction radiation beam 419 and split diffraction radiation beam 419 into at least two radiation sub-beams, according to an embodiment. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements may be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example embodiment, diffracted radiation sub-beam 429 can be at least a portion of radiation sub-beam 415 that may be reflected from alignment mark or target 418. In an example of this embodiment, interferometer 426 comprises any appropriate set of optical-elements, for example, a combination of prisms that may be configured to form two images of alignment mark or target 418 based on the received diffracted radiation sub-beam 429. It should be appreciated that a good quality image need not be formed, but that the features of alignment mark 418 should be resolved. Interferometer 426 can be further configured to rotate one of the two images with respect to the other of the two images 180° and recombine the rotated and unrotated images interferometrically.

In some embodiments, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference may be due to alignment mark or target 418 being 180° symmetrical, and the recombined image interfering constructively or destructively, according to an example embodiment. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further embodiment, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data may, for example, be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, beam analyzer 430 can be configured to receive and determine an optical state of diffracted radiation sub-beam 439. The optical state may be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some embodiments, beam analyzer 430 can be directly integrated into inspection apparatus 400, or connected via fiber optics of several types: polarization preserving single mode, multimode, or imaging, according to other embodiments.

In some embodiments, beam analyzer 430 can be further configured to determine the overlay data between two patterns on substrate 420. One of these patterns may be a reference pattern on a reference layer. The other pattern may be an exposed pattern on an exposed layer. The reference layer may be an etched layer already present on substrate 420. The reference layer may be generated by a reference pattern exposed on the substrate by lithographic apparatus 100 and/or 100′. The exposed layer may be a resist layer exposed adjacent to the reference layer. The exposed layer may be generated by an exposure pattern exposed on substrate 420 by lithographic apparatus 100 or 100′. The exposed pattern on substrate 420 can correspond to a movement of substrate 420 by stage 422. In some embodiments, the measured overlay data may also indicate an offset between the reference pattern and the exposure pattern. The measured overlay data may be used as calibration data to calibrate the exposure pattern exposed by lithographic apparatus 100 or 100′, such that after the calibration, the offset between the exposed layer and the reference layer may be minimized.

In some embodiments, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile may also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some embodiments, an array of detectors (not shown) may be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but require individual pre-amps. The number of elements is therefore limited. CCD linear arrays offer many elements that may be read-out at high speed and are especially of interest if phase-stepping detection is used.

In some embodiments, a second beam analyzer 430′ can be configured to receive and determine an optical state of diffracted radiation sub-beam 429, as shown in FIG. 4B. The optical state may be a measure of beam wavelength, polarization, or beam profile. Second beam analyzer 430′ can be identical to beam analyzer 430. Alternatively, second beam analyzer 430′ can be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some embodiments, second beam analyzer 430′ can be directly integrated into inspection apparatus 400, or it may be connected via fiber optics of several types: polarization preserving single mode, multimode, or imaging, according to other embodiments. Alternatively, second beam analyzer 430′ and beam analyzer 430 can be combined to form a single analyzer (not shown) configured to receive and determine the optical states of both diffracted radiation sub-beams 429 and 439.

In some embodiments, processor 432 receives information from detector 428 and beam analyzer 430. For example, processor 432 can be an overlay calculation processor. The information may comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some embodiments, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm may be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error may be deduced. Table 1 illustrates how this may be performed. The smallest measured overlay in the example shown is −1 nm. However this is in relation to a target with a programmed overlay of −30 nm. The process may have introduced an overlay error of 29 nm.

TABLE 1

| Programmed overlay | −70 | −50 | −30 | −10 | 10 | 30 | 50 |
|---|---|---|---|---|---|---|---|
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value may be taken to be the reference point and, relative to this, the offset may be calculated between measured overlay and that expected due to the programmed overlay. This offset determines the overlay error for each mark or the sets of marks with similar offsets. Therefore, in the Table 1 example, the smallest measured overlay was-1 nm, at the target position with programmed overlay of 30 nm. The difference between the expected and measured overlay at the other targets is compared to this reference. A table such as Table 1 may also be obtained from marks and target 418 under different illumination settings. The illumination setting, which results in the smallest overlay error, and its corresponding calibration factor, can be determined and selected from the table. The selected illumination setting may be used. Following this, processor 432 can group marks into sets of similar overlay error. The criteria for grouping marks can be adjusted based on different process controls, for example, different error tolerances for different processes.

In some embodiments, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection apparatus 400.

### Exemplary Beam Displacer for Increasing Inspection Throughput

In some embodiments, inspections tools can inspect multiple targets in parallel to increase fabrication throughput in a compact and cost-efficient way (i.e., without duplicating optical elements of the inspection apparatus). In some aspects, the inspection apparatus may take measurements from multiple targets on separate wafers.

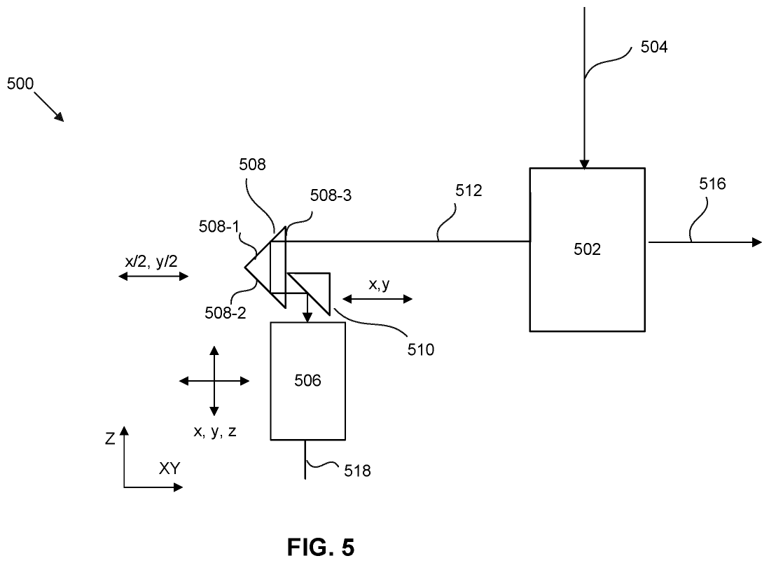

Referring again to FIGS. 4A and 4B, in some embodiments, inspection apparatus 400 (FIGS. 4A and/or 4B) can be modified so as to split radiation from illumination system 412 (in addition to the beam-splitting already shown in FIG. 4) as well as to have multiple detectors 428 for inspecting multiple targets 418. Though the multiple detectors and targets configuration is not expressly illustrated FIGS. 4A and 4B, their structures and functions will be described in reference to FIGS. 5, 6, 7, and 8 for allowing such a configuration. The term “collection optics,” “objective,” or the like may be used to refer to one or more optical elements that participate in the collection of scattered radiation from target 418 and/or other targets. For example, the objective in FIGS. 4A and/or 4B may include interferometer 426 and/or any lens(es), mirror(s), or other optical elements not expressly shown. In the configuration for measuring multiple targets using multiple detectors, it should be appreciated that corresponding multiple objectives may also be implemented.

In some embodiments, inspection apparatus 400 can include two or more objectives configured to collect scattered radiation from two targets on two separate wafers. Each objective may have a corresponding optical axis.

In some instances, modifying internal optics of an inspection apparatus for parallel measurements may present optical challenges. For example, a position of a first objective has to be adjusted relative to a second objective to accommodate for a shift in at least a lateral dimension (e.g., x-dimension) between the two separate wafers. Moving the objective relative to an optical path may decrease the optical performance of the inspection apparatus. Illumination used for inspection of lithographically printed features relies on specific illumination properties (e.g., polarization, diffraction order, modulation, or the like). To avoid a decrease in the optical performance, illumination properties should be maintained when adjusting the objectives. For example, a polarization of a reflected beam is either parallel to or perpendicular to the polarization of an incident beam. Thus, objectives should be moved relative to the other components of the inspection apparatus while maintaining the centering of the beam and all the other optical properties of the beam.

As suggested earlier, in some embodiments, scaling of optical hardware of inspection apparatus 400 can be performed while appreciating any impact to illumination properties. In some embodiments, a movable beam displacer may be used. In some aspects, the optical displacer is moved in the light path prior to the objective such as the optical axis is moved without affecting the optical properties of the beam. Optical properties of the beam are preserved because only optical elements that include flat surfaces (i.e., non-powered) are moved relative to the beam.

FIG. 5 shows an optical system 500 for directing radiation to a target, according to some embodiments. In some embodiments, optical system 500 can comprise an optical element 502, a beam displacer 508, an objective 506, and a fold mirror 510. Beam displacer 508 can comprise reflective surfaces 508-1 and 508-2. The two reflective surfaces are disclosed as a non-limiting example (e.g., more reflective surfaces may be used). In some embodiments, beam displacer 508 can be a prism, or the like. Reflective surfaces 508-1 and 508-2 can be facets of the prism. In some embodiments, the prism may be a Porro prism (e.g., right geometric prism with right angled triangular faces). In some embodiments, beam displacer 508 can be rotated by 90° around a first lateral direction (e.g., x-direction).

In some embodiments, optical system 500 can receive a beam of radiation 504 (e.g., from illumination system 412 (FIG. 4)). Beam of radiation 504 can be received at optical element 502. Optical element 502 can be a beam splitter system (one or more beam splitters). Optical element 502 can split beam of radiation 504 to generate beams of radiation 512, 516 (e.g., a first beam of radiation and a second beam of radiation). Beams of radiation 512 and 516 can be directed by optical system 500 to respective targets for inspection. A challenge arises if optical elements of optical system 500 are fixed relative to one another. If a separation between beams of radiation 512 and 516 is fixed at, for example, 1 cm, then performing inspection on targets that are not approximately 1 cm apart becomes difficult or not possible. Therefore, optical system 500 can comprise movable elements so as to control a displacement of an optical axis of one beam of radiation relative to the other beam of radiation.

In some embodiments, beam of radiation 512 can be controlled based on controlling a position of displaced optical axis 518 (e.g., by moving beam displacer 508). Based on the capabilities introduced by beam displacer 508, an inspection system may irradiate two targets (or more using additional beam displacers/splitters) even if a separation distance between the targets is allowed to vary. Beam displacer 508 can adjust a separation between beams of radiation 512 and 514 so as to correspond to the separation between the targets.

In some embodiments, optical system 500 can direct beam of radiation 512 toward a target (e.g., target 418 (FIG. 4)) so as to produce scattered radiation from the target. A detector (e.g., detector 428 (FIG. 4)) may receive the scattered radiation. Optical system 500 can direct beam of radiation 516 to toward a second target (not specifically shown) so as to produce second scattered radiation from the second target. A second detector (not specifically shown) may receive the second scattered radiation. When appropriate, beam displacer 508 can move so as to shift beam of radiation 512 such that it is possible to use both beams of radiation 512 and 516 to irradiate the target and the second target in parallel (e.g., as opposed to in sequence). The detector and second detector may generate respective measurement signals based on the scattered radiation and second scattered radiation. The inspection apparatus may perform parallel measurements of the target and second target using the detector and second detector, respectively.

In some embodiments, beam displacer 508 is moved linearly in a lateral x-y direction as opposed to e.g., a rotational movement. For example, in some methods that involve a rotating prism, the beam displacer has to be rotated while other optical elements may employ a translation mechanism that allow for linear movements and not a rotational movement. That may increase the complexity of the design. In addition, beam displacer 508 can displace/move the beam without passing through power elements or non-flat optical elements (e.g., lenses). For example, in some methods that involve cat's eye lens(es), the light beam may suffer from position dependent aberrations. In addition, methods that involve a relay system may focus light on a mirror. It is undesired to have the mirror in a focus point because the optical system becomes sensitive to a contamination or a scratch at that mirror.

In some embodiments, beam of radiation 512 can be received at beam displacer 508. Reflective surfaces 508-1 and 508-2 can perform reflections of beam of radiation 512 so as to alter optical axis. Beam displacer 508 can be movable in at least two dimensions. For example, beam displacer 508 can be movable in lateral directions x and y (i.e., x-direction and y-direction). Beam displacer 508 allows objective 506 to move by twice the amount as beam displacer 508.

As described previously herein, beam displacer 508 can comprise a prism. The prism may include a first surface 508-3, a second surface, and a third surface. Second surface and third surface may correspond to reflective surfaces 508-1 and 508-2. In some aspects, beam of radiation 512 first interacts with first surface 508-3. The beam of radiation 512 can be received at a substantially perpendicular direction to first surface 508-3. Beam of radiation 512 can be reflected by reflective surface 508-1 toward reflective surface 508-2. Beam of radiation 512 can exit the beam displacer 508 at first surface 508-3 at a substantially perpendicular direction to first surface 508-3. Beam of radiation 512 can be reflected by fold mirror 510 towards objective 506. Fold mirror 510 is configured to fold a x-shift to a y-shift. In some aspects, fold mirror 510 can move with objective 506 in the lateral directions x and y but does not move in the z-direction. In some aspects, one unit of motion of beam displacer 508 can correspond to two units of motion of fold mirror 510 while allowing the collected scattered radiation to stay aligned at an optical center of objective 506.

In some embodiments, optical system 500 can include one or more reflective elements (e.g., mirrors) (not specifically shown) configured to direct beam of radiation 512 from optical element 502 to first surface 508-3 of beam displacer 508.

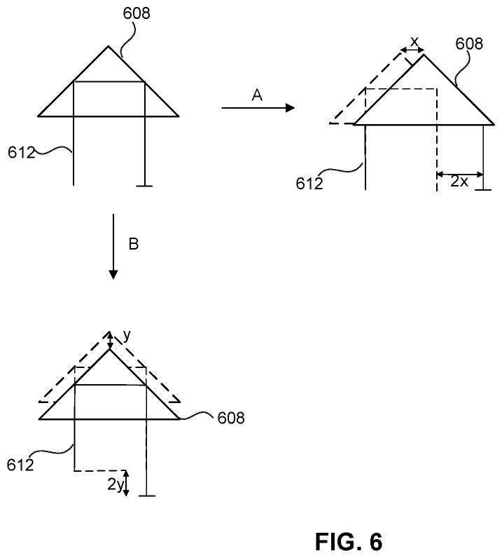

FIG. 6 is a schematic that shows a beam displacer, according to some embodiments. In some embodiments, a unit of movement of a beam displacer 608 in a x-direction may correspond to two units of movement for beam of radiation 612 in the x-direction. As illustrated by A, if beam displacer 608 is moved x units in the x-direction, beam of radiation is moved by two times x. In addition, a unit of movement of beam displacer 608 in a y-direction may correspond to two units of movements for beam of radiation 608 in the y-direction. As illustrated by B, if beam displacer 608 is moved y units in the y-direction, beam of radiation 612 is moved two times y. Thus, objective of inspection apparatus (e.g., inspection apparatus 400 of FIG. 4A) may move with double of the movement of beam displacer 608.

In some embodiments, in order to maintain the beam centered with the objective, optical elements of the beam displacer 608 (e.g., prism assembly) are moved half as far as the objective. If the objective is moved twice as far, the beam stays centered with respect to the objective and the performance is maintained.

In some embodiments, beam displacer (e.g., beam displacer 508 of FIG. 5) is moved in lateral x and/or y directions at a first speed. Other optical elements (e.g., fold mirror 510 of FIG. 5) may be moved in the lateral x and/or y directions at a second speed while objective 506 of FIG. 5 may be moved in the lateral x and/or y directions at the second speed and in the z-direction at a third speed. From a mechatronic perspective, having three components (objective, fold mirror and beam displacer) that move differently (i.e., direction and/or speed) is likely to result in a complex system. Therefore, it may desired to limit the optical elements that requires distinct control mechanisms.

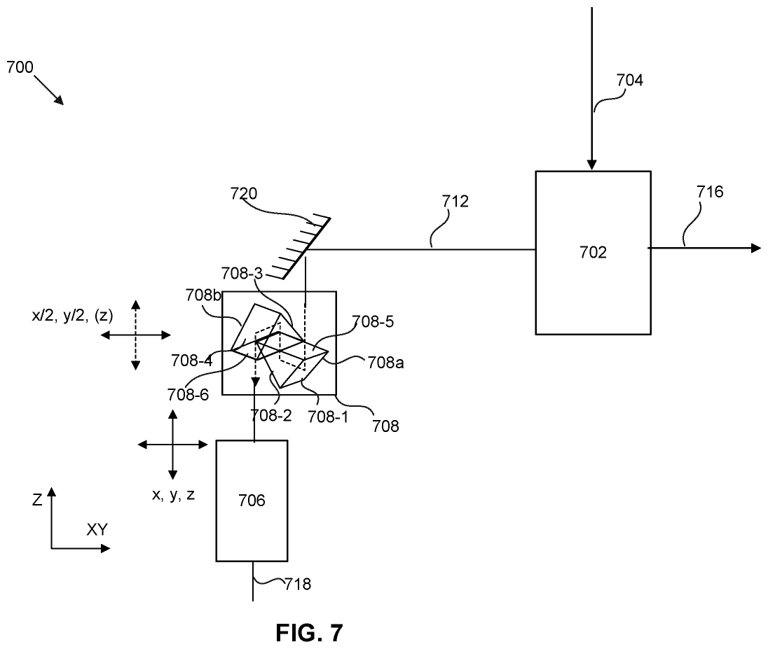

FIG. 7 shows an optical system 700 for directing radiation to a target, according to some embodiments. In some embodiments, optical system 700 can comprise an optical element 702, a beam displacer 708, an objective 706, and a reflective element 720. Beam displacer 708 can comprise reflective surfaces 708-1, 708-2, 708-3, and 708-4. The four reflective surfaces are disclosed as a non-limiting example (e.g., more reflective surfaces may be used). In some embodiments, beam displacer 708 can be a double prism, or the like. Reflective surfaces 708-1, 708-2, 708-3, and 708-4 can be facets of the double prism. In some embodiments, the double prism may be a double Porro prism.

In some embodiments, optical system 700 can receive a beam of radiation 704 (e.g., from illumination system 412 (FIG. 4)). Beam of radiation 704 can be received at optical element 702. Optical element 702 can be a beam splitter. Optical element 702 can split beam of radiation 704 to generate beams of radiation 712, 716 (e.g., a first beam of radiation and a second beam of radiation). Beams of radiation 712 and 716 can be directed by optical system 700 to respective targets for inspection. As described above, optical system 700 can comprise movable elements so as to control a displacement of an optical axis of one beam of radiation relative to the other beam of radiation.

In some embodiments, beam of radiation 712 can be controlled based on controlling a position of displaced optical axis 718 (e.g., by moving beam displacer 708). Based on the capabilities introduced by beam displacer 708, an inspection system may irradiate two targets (or more using additional beam displacers/splitters) even if a separation distance between the targets is allowed to vary. Beam displacer 708 can adjust a separation between beams of radiation 712 and 716 so as to correspond to the separation between the targets.

In some embodiments, optical system 700 can direct beam of radiation 712 toward a target (e.g., target 418 (FIG. 4)) so as to produce scattered radiation from the target. A detector (e.g., detector 428 (FIG. 4)) may receive the scattered radiation. Optical system 700 can direct beam of radiation 716 toward a second target (not specifically shown) so as to produce second scattered radiation from the second target. A second detector (not specifically shown) may receive the second scattered radiation. When appropriate, beam displacer 708 can move so as to shift beam of radiation 712 such that it is possible to use both beams of radiation 712 and 716 to irradiate the target and the second target in parallel (e.g., as opposed to in sequence). The detector and second detector may generate respective measurement signals based on the scattered radiation and second scattered radiation. The inspection apparatus may perform parallel measurements of the target and second target using the detector and second detector, respectively.

In some embodiments, beam of radiation 712 can be received at beam displacer 708. In some aspects, reflective element 720 (e.g., a mirror or a reflective system) can direct beam of radiation 712 toward beam displacer 708. Beam displacer 708 can be movable in at least two dimensions. For example, beam displace 708 can be movable in lateral directions x and y. In some embodiments, beam displacer 708 can move with half the x/y-movement of objective 706. In some aspects, a z-distance between beam displacer 708 and objective 706 can change without affecting the optical properties of beam 712.

As described previously herein, beam displacer 708 can comprise a double prism (a first prism 708a and a second prism 708b). First prism 708a can include a first surface 708-5, a second surface, and a third surface. Second surface and third surface may correspond to reflective surfaces 708-1 and 708-2. Second prism 708b can include a first surface 708-6, a second surface, and a third surface. Second surface and third surface of second prism 708b can correspond to reflective surfaces 708-3 and 708-4. Reflective surfaces 708-1, 708-2, 708-3, and 708-4 can perform reflections of beam of radiation 712 so as to alter optical axis (illustrated as a displaced optical axis 718). The reflections at reflective surfaces 708-1, 708-2, 708-3, and 708-4 can be, for example, total internal reflections within the prism, partial reflections, reflections by a metallic surface, or the like.

In some aspects, beam of radiation 712 first interacts with first surface 708-5. The beam of radiation 712 can be received at a substantially perpendicular direction to first surface 708-5. Beam of radiation 712 can be reflected by reflective surface 708-1 toward reflective surface 708-2. Beam of radiation 712 can exit the beam displacer 708 at first surface 708-5 at a substantially perpendicular direction to first surface 708-3. Beam of radiation 712 can enter second prism 708b at first surface 708-6 at a substantially perpendicular direction to first surface 708-6. Beam of radiation 712 can be reflected by reflective surfaces 708-3 and 708-4 and exits second prism 708b via first surface 708-6 at a substantially perpendicular direction to first surface 708-6 of second prism 708b. In some aspects, first surface 708-6 of second prism 708b and first surface 708-5 of first prism 708a can be cemented together, in a double Porro arrangement as would be understood by one of ordinary skill in the art.

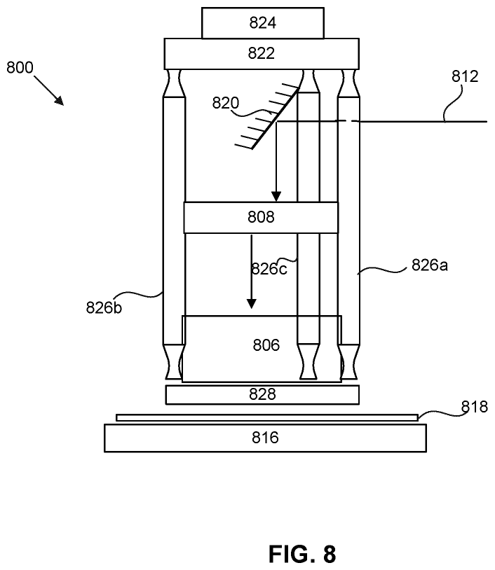

FIG. 8 shows a mounting arrangement for a beam displacer, according to some embodiments. In some embodiments, a desired one to two ratio between a beam displacer 808 (e.g., beam displacer 508 of FIG. 5, beam displacer 708 of FIG. 7) and an objective 806 may be achieved using a z-stage 800. In some embodiments, objective 806 and beam displacer 808 (e.g., double Porro-prism) are connected to z-stage 800 via three or more flexures (e.g., XY-flexures 826a, 826b, 826c). In some aspects, each flexure is flexible in at least two degrees of freedom.

In some aspects, a reflective element 820 can direct a beam of radiation 812 towards beam displacer 808. Objective 806 can direct beam 812 towards a substrate 818 placed on a stage 816.

In some embodiments, an actuator 828 can control a movement of objective 806 and beam displacer 808 in lateral directions x and y. Beam displacer 808 can be connected at the middle of flexures 826a, 826b, and 826c that results in the desired 1:2 motion ratio between beam displacer 808 and objective 806.

In some embodiments, an actuator 822 can control the movement of objective 806 in a z-direction. In some embodiments, z-stage 800 can also include a z-flexure 824. Actuator 822 can be coupled with z-flexure 824.

In some embodiments, a first stage may be used to control the movement of beam displacer and a second stage is used to control the movement of the objective. The first stage may be configured to move at half-speed of the second stage.

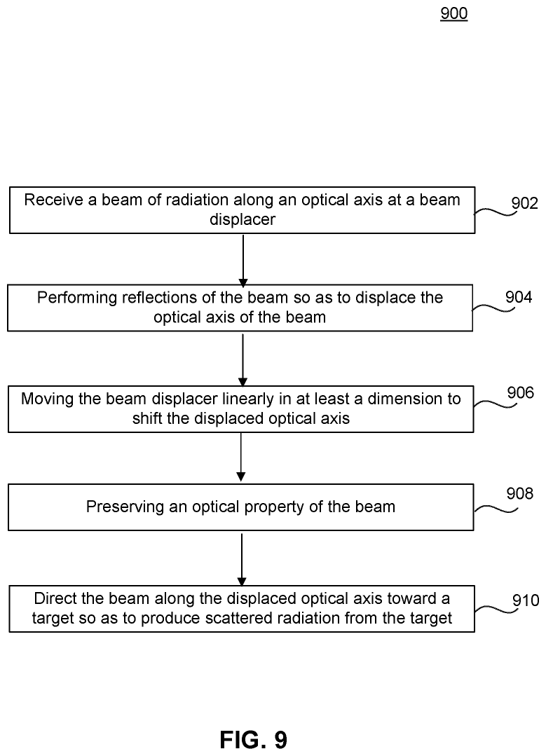

FIG. 9 shows a flowchart 900 of method steps for performing functions as described in reference to at least FIGS. 4A, 4B, 5, 6, 7, and/or 8, according to some embodiments.

At step 902, a beam of radiation may be received along the optical axis at a beam displacer.

At step 904, reflections of the beam may be performed using at least two reflective surfaces of the beam displacer so as to displace the optical axis of the beam. At step 906, the beam displacer may be moved in a linear fashion to shift the displaced optical axis. At step 908, an optical property of the beam may be preserved such that an optical property of the beam along the deflected optical axis is invariant to the linear movement of the beam displacer. At step 910, the beam may be directed along the optical axis toward a target so as to produce scattered radiation from the target.

The method steps of FIG. 9 may be performed in any conceivable order and it is not required that all steps be performed. Moreover, the method steps of FIG. 9 described above merely reflect an example of steps and are not limiting. That is, further method steps and functions may be envisaged based upon embodiments described in reference to FIGS. 1-8.

The embodiments may further be described using the following clauses:
1. An inspection apparatus comprising:
a radiation source configured to generate a beam of radiation;
an optical system configured to receive and direct the beam along an optical axis and toward a target so as to produce scattered radiation from the target, the optical system comprising:
a beam displacer comprising two or more reflective surfaces, wherein the beam displacer is configured to:
receive the beam along the optical axis;
perform reflections of the beam so as to displace the optical axis of the beam;
move linearly in at least a first dimension to shift the displaced optical axis; and
preserve an optical property of the beam such that the optical property is invariant to the linear movement; and
a detector configured to receive the scattered radiation and to generate a measurement signal based on the scattered radiation.
2. The inspection apparatus of clause 1, wherein
the beam displacer comprises a first prism and a second prism, wherein:
each of the first prism and the second prism have at least a respective first surface, second surface, and third surface;
the second surface and the third surface of the first prism and the second surface and the third surface of the second prism total four reflective surfaces;
the first surface of the first prism is configured to receive the beam at a substantially perpendicular direction to the first surface of the first prism;
the second and third surfaces of the first prism are configured to reflect the beam toward the first surface of the second prism; and
the first surface of second prism is configured to direct the beam toward an objective of the optical system at a substantially perpendicular direction to the first surface of the second prism.
3. The inspection apparatus of clause 2, wherein the optical system further comprises a reflective element configured to direct the beam toward the first surface of the first prism.
4. The inspection apparatus of clause 1, wherein:
the beam displacer comprises a prism;
the optical system further comprises a fold mirror configured to reflect the beam toward an objective of the optical system; and
two units of motion of the objective moves the beam displacer one unit of motion so that the beam can be aligned to an optical center of the objective of the optical system.
5. The inspection apparatus of clause 4, wherein the optical system further comprises:
a reflective element configured to direct the beam along the optical axis and toward a first surface of the prism.
6. The inspection apparatus of clause 1, wherein the optical system comprises an objective having an optical center, and the optical system is configured to collect and direct the scattered radiation toward the detector; and two units of motion of the objective moves the beam displacer one unit of motion to allow the scattered radiation to be aligned to the optical center.
7. The inspection apparatus of clause 6, further comprising:
a mounting device comprising three or more flexure elements and configure to mount the beam displacer and the objective, and wherein each of the three or more flexure elements is flexible in at least two degrees of freedom.
8. The inspection apparatus of clause 7, wherein the beam displacer and the objective are positioned on the mounting device such that one unit of motion of the objective results in a half unit of motion for the beam displacer.
9. The inspection apparatus of clause 1, wherein the optical system further comprises a beam splitter configured to split the beam to generate a second beam of radiation.
10. The inspection apparatus of clause 9, further comprising a second detector, wherein:
the optical system is configured to direct the second beam toward a second target so as to produce second scattered radiation from the second target;
the second detector is configured to receive the second scattered radiation and to generate a second measurement signal based on the second scattered radiation; and
the beam displacer is configured to adjust a separation between the beam and the second beam so as to correspond to a separation between the target and the second target.
11. An optical element comprising:
at least two reflective surfaces, configured with respect to each other to:
receive a beam of radiation along an optical axis;
perform reflections of the beam so as to displace the optical axis of the beam;
move linearly in at least a first dimension to shift the displaced optical axis; and
preserve an optical property of the beam such that the optical property is invariant to the linear movement.
12. The optical element of clause 11, wherein the at least two reflective surfaces comprises four reflective surfaces and the optical element further comprising a first prism and a second prism, wherein: the first prism and the second prism have at least a first surface, a second surface, and a third surface; the second surface and the third surface of the first prism and the second prism correspond to four reflective surfaces;
the first surface of the first prism is configured to receive the beam at a substantially perpendicular direction to the first surface of the first prism, the second and third surfaces of the first prism are configured to reflect the beam toward the first surface of the second prism; and the first surface of second prism is configured to direct the beam toward an objective at a substantially perpendicular direction to the first surface of the second prism.
13. A method comprising:
receiving a beam of radiation along an optical axis at a beam displacer;
performing reflections of the beam so as to displace the optical axis of the beam using two or more reflective surfaces of the beam displacer;
moving the beam displacer linearly in at least a dimension to shift the displaced optical axis;
preserving an optical property of the beam such that the optical property of the beam along the deflected optical axis is invariant to the linear movement; and
directing the beam along the deflected optical axis toward a target so as to produce scattered radiation from the target.
14. The method of clause 13, further comprising:
moving an objective of an inspection apparatus two units of motion moves the beam displacer one unit of motion so that the beam can be aligned to an optical center of the objective of the inspection apparatus.
15. The method of clause 13, further comprising:
receiving the beam from the beam displacer;
reflecting the beam from the beam displacer toward a fold mirror; and
moving the fold mirror two units of motion thus causing the beam displacer to move only one unit of motion.
16. The method of clause 13, further comprising:
receiving the scattered radiation at a detector of an inspection apparatus; and
generating a measurement signal based on the scattered radiation using the detector.
17. The method of clause 13, further comprising splitting the beam to generate a second beam of radiation using a beam splitter.
18. The method of clause 17, further comprising:
directing the second beam toward a second target so as to produce second scattered radiation from the second target;
receiving the second scattered radiation at a second detector of the inspection apparatus; and
generating a second measurement signal based on the second scattered radiation using the second detector.
19. The method of clause 18, further comprising adjusting a separation between the beam and the second beam so as to correspond to a separation between the target and the second target using the beam displacer.
20. The method of clause 13, further comprising:
collecting the scattered radiation using an objective having an optical center;
directed the collected scattered radiation toward the detector using the objective, wherein
two units of motion of the objective for one unit of motion of the beam displacer allows the scattered radiation to be aligned to the optical center.

For example, in some embodiments, the scattered radiation may be received at a detector of an inspection apparatus. A measurement signal may be generated using the detector based on the scattered radiation. The beam may be split using a beam splitter to generate a second beam of radiation. The second beam may be directed toward a second target so as to produce second scattered radiation from the second target. The second scattered radiation may be received at a second detector of the inspection apparatus. A second measurement signal may be generated using the second detector based on the second scattered radiation. Parallel measurements of the target and the second target may be performed using the detector and the second detector, respectively. A separation between the beam and the second beam may be adjusted using the beam displacer so as to correspond to a separation between the target and the second target. The scattered radiation may be collected using an objective having an optical center. The collected scattered radiation may be directed toward the detector using the objective, wherein one unit of motion of the objective for half-unit of motion of the beam displacer allows the scattered radiation to be aligned to the optical center.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as specific examples of the more general terms “substrate” or “target portion”, respectively. The substrate referred to herein can be processed, before or after exposure, in for example a track unit (a tool that typically applies a layer of resist to a substrate and develops the exposed resist) and/or a metrology unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam of radiation” or the like as used herein can encompass all types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as matter beams, such as ion beams or electron beams. The terms “light,” “illumination,” or the like can refer to non-matter radiation (e.g., photons, UV, X-ray, or the like). Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1.-20. (canceled)

21. An inspection apparatus comprising:
a radiation source configured to generate a beam of radiation;
an optical system configured to receive and direct the beam along an optical axis and toward a target so as to produce scattered radiation from the target, the optical system comprising:
a beam displacer comprising two or more reflective surfaces, wherein the beam displacer is configured to:
receive the beam along the optical axis;
perform reflections of the beam so as to displace the optical axis of the beam;
move linearly in at least a first dimension to shift the displaced optical axis; and
preserve an optical property of the beam such that the optical property is invariant to the linear movement; and
a detector configured to receive the scattered radiation and to generate a measurement signal based on the scattered radiation.

22. The inspection apparatus of claim 21, wherein
the beam displacer comprises a first prism and a second prism, wherein:
each of the first prism and the second prism have at least a respective first surface, second surface, and third surface;
the second surface and the third surface of the first prism and the second surface and the third surface of the second prism total four reflective surfaces;
the first surface of the first prism is configured to receive the beam at a substantially perpendicular direction to the first surface of the first prism;
the second and third surfaces of the first prism are configured to reflect the beam toward the first surface of the second prism; and
the first surface of second prism is configured to direct the beam toward an objective of the optical system at a substantially perpendicular direction to the first surface of the second prism.

23. The inspection apparatus of claim 22, wherein the optical system further comprises a reflective element configured to direct the beam toward the first surface of the first prism.

24. The inspection apparatus of claim 21, wherein:
the beam displacer comprises a prism;
the optical system further comprises a fold mirror configured to reflect the beam toward an objective of the optical system; and
two units of motion of the objective moves the beam displacer one unit of motion so that the beam can be aligned to an optical center of the objective of the optical system.

25. The inspection apparatus of claim 24, wherein the optical system further comprises: a reflective element configured to direct the beam along the optical axis and toward a first surface of the prism.

26. The inspection apparatus of claim 21, wherein the optical system comprises an objective having an optical center, and the optical system is configured to collect and direct the scattered radiation toward the detector; and
two units of motion of the objective moves the beam displacer one unit of motion to allow the scattered radiation to be aligned to the optical center.

27. The inspection apparatus of claim 26, further comprising:
a mounting device comprising three or more flexure elements and configure to mount the beam displacer and the objective, and wherein each of the three or more flexure elements is flexible in at least two degrees of freedom.

28. The inspection apparatus of claim 27, wherein the beam displacer and the objective are positioned on the mounting device such that one unit of motion of the objective results in a half unit of motion for the beam displacer.

29. The inspection apparatus of claim 21, wherein the optical system further comprises a beam splitter configured to split the beam to generate a second beam of radiation.

30. The inspection apparatus of claim 29, further comprising a second detector, wherein:
the optical system is configured to direct the second beam toward a second target so as to produce second scattered radiation from the second target;
the second detector is configured to receive the second scattered radiation and to generate a second measurement signal based on the second scattered radiation; and
the beam displacer is configured to adjust a separation between the beam and the second beam so as to correspond to a separation between the target and the second target.

31. An optical element comprising:
at least two reflective surfaces, configured with respect to each other to:
receive a beam of radiation along an optical axis;
perform reflections of the beam so as to displace the optical axis of the beam;
move linearly in at least a first dimension to shift the displaced optical axis; and
preserve an optical property of the beam such that the optical property is invariant to the linear movement.

32. The optical element of claim 31, wherein the at least two reflective surfaces comprises four reflective surfaces and the optical element further comprising a first prism and a second prism, wherein:
the first prism and the second prism have at least a first surface, a second surface, and a third surface;
the second surface and the third surface of the first prism and the second prism correspond to four reflective surfaces;
the first surface of the first prism is configured to receive the beam at a substantially perpendicular direction to the first surface of the first prism, the second and third surfaces of the first prism are configured to reflect the beam toward the first surface of the second prism; and
the first surface of second prism is configured to direct the beam toward an objective at a substantially perpendicular direction to the first surface of the second prism.

33. A method comprising:
receiving a beam of radiation along an optical axis at a beam displacer;
performing reflections of the beam so as to displace the optical axis of the beam using two or more reflective surfaces of the beam displacer;
moving the beam displacer linearly in at least a dimension to shift the displaced optical axis;
preserving an optical property of the beam such that the optical property of the beam along the deflected optical axis is invariant to the linear movement; and
directing the beam along the deflected optical axis toward a target so as to produce scattered radiation from the target.

34. The method of claim 33, further comprising moving an objective of an inspection apparatus two units of motion moves the beam displacer one unit of motion so that the beam can be aligned to an optical center of the objective of the inspection apparatus.

35. The method of claim 33, further comprising:
receiving the beam from the beam displacer;
reflecting the beam from the beam displacer toward a fold mirror; and
moving the fold mirror two units of motion thus causing the beam displacer to move only one unit of motion.

36. The method of claim 33, further comprising:
receiving the scattered radiation at a detector of an inspection apparatus; and
generating a measurement signal based on the scattered radiation using the detector.

37. The method of claim 33, further comprising splitting the beam to generate a second beam of radiation using a beam splitter.

38. The method of claim 37, further comprising:
directing the second beam toward a second target so as to produce second scattered radiation from the second target;
receiving the second scattered radiation at a second detector of the inspection apparatus; and
generating a second measurement signal based on the second scattered radiation using the second detector.

39. The method of claim 38, further comprising adjusting a separation between the beam and the second beam so as to correspond to a separation between the target and the second target using the beam displacer.

40. The method of claim 33, further comprising:
collecting the scattered radiation using an objective having an optical center; and
directing the collected scattered radiation toward the detector using the objective, wherein two units of motion of the objective for one unit of motion of the beam displacer allows the scattered radiation to be aligned to the optical center.
